(19) United States
(12) Patent Application Publication
(10) Pub. No.: US 2024/0297018 A1
(43) Pub. Date: Sep. 5, 2024

(54) DISTRIBUTOR AND PLASMA PROCESSING APPARATUS

(71) Applicant: Tokyo Electron Limited, Tokyo (JP)

(72) Inventors: Taro IKEDA, Nirasaki City (JP); Yuki OSADA, Nirasaki City (JP); Hiroyuki MIYASHITA, Nirasaki City (JP)

(21) Appl. No.: 18/589,744

(22) Filed: Feb. 28, 2024

(30) Foreign Application Priority Data
Mar. 1, 2023 (JP) 2023-031281

(51) Int. Cl. H01J 37/32

(52) U.S. Cl. CPC H01J 37/32183; H01J 37/3211; H01J 2237/327

(57) ABSTRACT

A distributor for distributing electromagnetic waves to a plurality of output terminals, the distributor includes: a power supply terminal configured to be electrically connected to a radio-frequency power source configured to be capable of varying frequency; and a plurality of filters provided respectively at the plurality of output terminals to which the electromagnetic waves input to the power supply terminal are distributed. The plurality of filters is configured to have different frequency characteristics.

### CROSS-REFERENCE TO RELATED APPLICATION

This application is based upon and claims the benefit of priority from Japanese Patent Application No. 2023-031281, filed on Mar. 1, 2023, the entire contents of which are incorporated herein by reference.

### TECHNICAL FIELD

The present disclosure relates to a distributor and a plasma processing apparatus.

### BACKGROUND

In an inductively coupled plasma processing apparatus, an RF antenna provided on a dielectric window is divided in a radial direction into an inner coil, an intermediate coil, and an outer coil. In a case in which a circulation is made from a radio-frequency power source to a ground potential member through an RF feeding line, an RF antenna, and a ground line, or more simply, in a case in which a circulation is made from a first node NA to a second node NB through a radio-frequency branch transmission path of each coil, counterclockwise circulation is made at the inner coil and the outer coil, whereas clockwise circulation is made at the intermediate coil. Variable intermediate and outer condensers are electrically connected in series, respectively, to the intermediate and outer coils, between the first node NA and the second node NB. A synthetic reactance Zo of the outer coil and the outer condenser is varied by varying a capacitance C of the outer condenser. Further, adjustment of a distribution ratio between an inner current Ii and an outer current Io is disclosed (Patent Document 1).

### PRIOR ART DOCUMENTS

### Patent Document

Patent Document 1: Japanese Patent Laid-Open Publication No. 2015-130350

### SUMMARY

According to one embodiment of the present disclosure, there is provided a distributor for distributing electromagnetic waves to a plurality of output terminals. The distributor includes: a power supply terminal configured to be electrically connected to a radio-frequency power source configured to be capable of varying frequency; and a plurality of filters provided respectively at the plurality of output terminals to which the electromagnetic waves input to the power supply terminal are distributed. The plurality of filters is configured to have different frequency characteristics

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a plasma processing apparatus according to a first embodiment of the present disclosure.

FIG. 2 is a perspective view illustrating an example of an antenna unit in the first embodiment.

FIG. 3 is a cross-sectional view illustrating an example of a distributor taken along line A-A in FIG. 2.

FIG. 4 is a diagram schematically illustrating an example of a microwave radiator in the first embodiment.

FIG. 5 is a cross-sectional view illustrating an example of a vicinity of an output terminal in the first embodiment.

FIG. 6 is a diagram illustrating an example of a method of controlling a power distribution ratio.

FIG. 7 is a diagram illustrating an example of frequency characteristics of a single filter in the first embodiment.

FIG. 8 is a diagram illustrating an example of frequency characteristics of a distributor in the first embodiment.

FIG. 9 is a perspective view illustrating an example of an antenna unit in a second embodiment.

FIG. 10 is a diagram schematically illustrating an example of a combination of resonance frequencies of filters in the second embodiment.

FIG. 11 is a diagram illustrating an example of a combination of a resonance frequency of a filter and a frequency of radio-frequency power in the second embodiment.

FIG. 12 is a timing chart illustrating an example of change in a frequency of radio-frequency power in the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a distributor and a plasma processing apparatus disclosed will be described in detail based on the drawings. The disclosed technology is not limited to the following embodiments.

In the inductively coupled plasma processing apparatus of Patent Document 1 mentioned above, the synthetic reactance Zo of the outer coil and the outer capacitor is varied by varying the capacitance C of the outer condenser to adjust the distribution ratio between the inner current and the outer current. On the other hand, in a microwave plasma type plasma processing apparatus, a power distributor is used upon distributing radio-frequency power. However, although the power distributor in the related art may distribute power equally, it has difficulty distributing power at a specific ratio or varying the distribution ratio. Therefore, it is necessary to vary the power distribution ratio.

### First Embodiment

### [Configuration of Plasma Processing Apparatus 100]

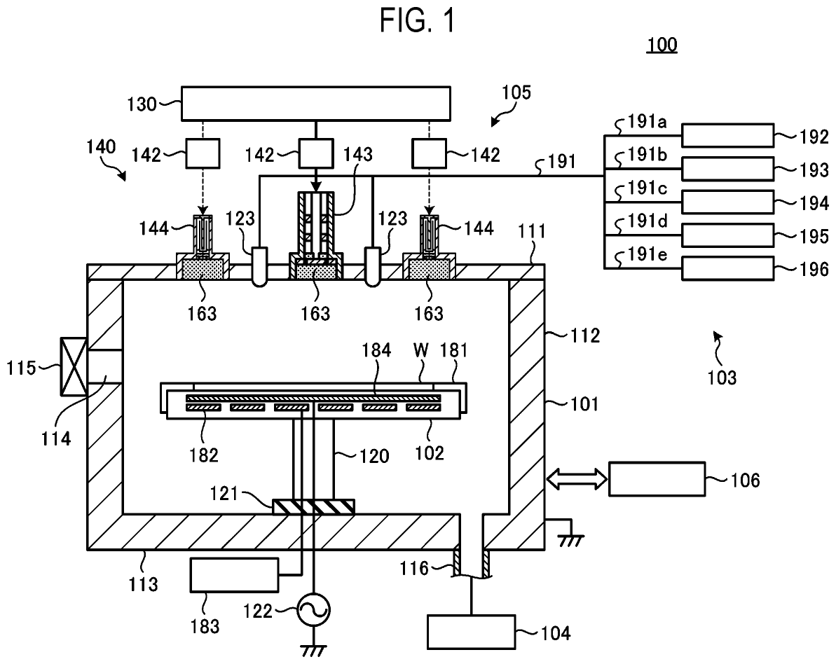

FIG. 1 is a schematic cross-sectional view illustrating an example of a plasma processing apparatus according to a first embodiment of the present disclosure. A plasma processing apparatus 100 illustrated in FIG. 1 includes a processing container 101, a stage 102, a gas supply 103, an exhauster 104, a microwave introducer 105, and a controller 106. The processing container 101 accommodates a substrate W. The substrate W is placed on the stage 102. The gas supply 103 supplies a gas into the processing container 101. The exhauster 104 exhausts an interior of the processing container 101. The microwave introducer 105 generates microwaves for generating plasma in the processing container 101 and also introduces the microwaves into the processing container 101. The controller 106 controls the operation of each portion of the plasma processing apparatus 100.

The processing container 101 is made of a metal material such as aluminum or an aluminum alloy and has a substantially cylindrical shape. The processing container 101 has a ceiling wall portion 111 and a bottom wall portion 113 of a plate shape, and a side wall portion 112 connecting the ceiling wall portion 111 and the bottom wall portion 113. The microwave introducer 105 is provided in an upper portion of the processing container 101 and functions as a plasma generator for generating plasma by introducing electromagnetic waves (microwaves) into the processing container 101. The microwave introducer 105 will be described in detail later.

The ceiling wall portion 111 has a plurality of openings into which a microwave radiator, a filter, and a gas introducer, which will be described later, of the microwave introducer 105 are fitted. The side wall portion 112 has a loading/unloading port 114 for loading/unloading the substrate W, which is a target substrate, to/from a transfer chamber (not shown) adjacent to the processing container 101. The loading/unloading port 114 is configured to be opened and closed by a gate valve 115. The bottom wall portion 113 is provided with the exhauster 104. The exhauster 104 is provided at an exhaust pipe 116 connected to the bottom wall portion 113 and includes a vacuum pump and a pressure control valve. The interior of the processing container 101 is exhausted via the exhaust pipe 116 by the vacuum pump of the exhauster 104. The pressure within the processing container 101 is controlled by the pressure control valve.

The stage 102 has a disc shape and is made of a ceramic such as AlN. The stage 102 is supported by a support member 120 of a cylindrical shape, which is made of a ceramic such as AlN and extends upward from the center of the bottom of the processing container 101, and by a base member 121. A guide ring 181 for guiding the substrate W is provided at an outer edge of the stage 102. Further, a lifting pin (not shown) for raising and lowering the substrate W is provided inside the stage 102 so as to be capable of protruding and retracting with respect to the upper surface of the stage 102.

In addition, a resistance heating type heater 182 is embedded inside the stage 102, and the heater 182 heats the substrate W thereon via the stage 102 by being supplied with power from a heater power source 183. Further, a thermocouple (not shown) is inserted into the stage 102, so that a heating temperature of the substrate W is controlled to a predetermined temperature in a range of, for example, 300 degrees C. to 1,000 degrees C., based on a signal from the thermocouple. In addition, an electrode 184 having approximately the same size as the substrate W is embedded above the heater 182 in the stage 102, and a radio-frequency bias power source 122 is electrically connected to the electrode 184. A radio-frequency bias for drawing ions is applied to the stage 102 from the radio-frequency bias power source 122. The radio-frequency bias power source 122 may not be provided depending on characteristics of plasma processing.

The gas supply 103 serves to introduce a plasma generation gas and a raw material gas, for example, for forming a graphene film (carbon-containing film), into the processing container 101 and has a plurality of gas introduction nozzles 123. The gas introduction nozzles 123 are fitted into the openings formed in the ceiling wall portion 111 of the processing container 101. A gas supply pipe 191 is connected to the gas introduction nozzles 123. This gas supply pipe 191 is branched into five branch pipes 191a, 191b, 191c, 191d, and 191e. An Ar gas supply source 192, an O₂ gas supply source 193, an N₂ gas supply source 194, an H₂ gas supply source 195, and a C₂H₂ gas supply source 196 are connected to these branch pipes 191a, 191b, 191c, 191d, and 191e. The Ar gas supply source 192 supplies an Ar gas as a noble gas (rare gas), which is a plasma generation gas. The O₂ gas supply source 193 supplies an O₂ gas as an oxidizing gas, which is a cleaning gas. The N₂ gas supply source 194 supplies an N₂ gas used as a purge gas or the like. The H₂ gas supply source 195 supplies an H₂ gas as a reducing gas. The C₂H₂ gas supply source 196 supplies an acetylene (C₂H₂) gas as a carbon-containing gas, which is a film forming raw material gas. The C₂H₂ gas supply source 196 may supply other carbon-containing gases such as ethylene (C₂H₄).

The branch pipes 191a, 191b, 191c, 191d, and 191e are provided with, although not shown, a mass flow controller for controlling flow rate and valves located before and after the mass flow controller. Further, a shower plate may be provided to supply the C₂H₂ gas and the H₂ gas to a position close to the substrate W, thereby adjusting gas dissociation. Moreover, the same effect may be obtained by extending the nozzles for supplying these gases downward.

As described above, the microwave introducer 105 is provided above the processing container 101 and functions as a plasma generator that introduces electromagnetic waves (microwaves) into the processing container 101 to generate plasma.

The microwave introducer 105 includes the ceiling wall portion 111 of the processing container 101, a microwave output portion 130, and an antenna unit 140. The ceiling wall portion 111 functions as a ceiling plate. The microwave output portion 130 generates microwaves, and distributes and outputs the microwaves to a plurality of paths. The antenna unit 140 introduces the microwaves output from the microwave output portion 130 into the processing container 101.

The microwave output portion 130 includes a microwave power source, a microwave oscillator, an amplifier, and a distributor. The microwave oscillator is a solid-state oscillator and oscillates microwaves (e.g., PLL oscillation) at, for example, 860 MHz. The frequency of the microwaves is not limited to 860 MHz and may use a range of 700 MHz to 10 GHz such as 2.45 GHz, 8.35 GHz, 5.8 GHz, and 1.98 GHz. Further, the microwave oscillator may vary an oscillation frequency by, for example, frequency modulation. The amplifier amplifies the microwaves oscillated by the microwave oscillator. The distributor distributes the microwaves amplified by the amplifier to multiple paths. The distributor distributes the microwaves while matching impedance between an input side and an output side.

The antenna unit 140 includes a microwave radiator 143 arranged at the center of the ceiling wall portion 111 and a plurality of filters 144 arranged on a same circumference so as to surround the microwave radiator 143. A distributor 170, which will be described later, includes, for example, two filters 144 and a tuner 154a, which is be described later, and, for example, three distributors 170 are arranged around the microwave radiator 143. That is, for example, six filters 144 are arranged around the microwave radiator 143. Amplifiers 142 are respectively provided between the microwave output portion 130 and the microwave radiator 143 and between the microwave output portion 130 and the distributor 170. The microwaves distributed by the distributor of the microwave output portion 130 are amplified by the amplifiers 142. The microwaves output from the amplifiers 142 are radiated into the processing container 101 from an antenna portion 156, which will be described later, via the microwave radiator 143 and each filter 144.

The amplifiers 142 include a phase shifter, a variable gain amplifier, a main amplifier, and an isolator. The phase shifter changes the phase of the microwaves. The variable gain amplifier adjusts a power level of the microwaves input to the main amplifier. The main amplifier is configured as a solid-state amplifier. The isolator separates reflected microwaves that are reflected by the antenna portion 156, which will be described later, and are directed toward the main amplifier.

Microwave transmission plates 163 fitted into the ceiling wall portion 111 are provided on a lower surface side of the antenna portion 156, which will be described later, and lower surfaces thereof are exposed to an internal space of the processing container 101. The microwaves transmitted through the microwave transmission plates 163 generate plasma in a space inside the processing container 101.

The controller 106 is typically composed of a computer and is configured to control each portion of the plasma processing apparatus 100. The controller 106 includes a storage, which stores a process sequence of the plasma processing apparatus 100 and a process recipe corresponding to control parameters of the plasma processing apparatus 100, an input means, a display, and the like, and is capable of performing predetermined control according to a selected process recipe. For example, the controller 106 controls each portion of the plasma processing apparatus 100 to perform film formation processing.

### [Structure of Antenna Unit 140]

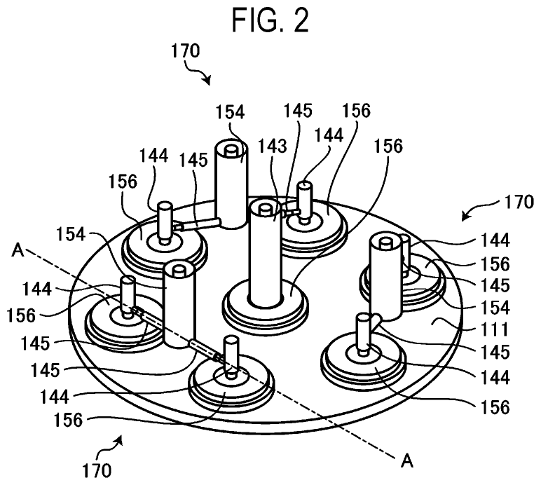

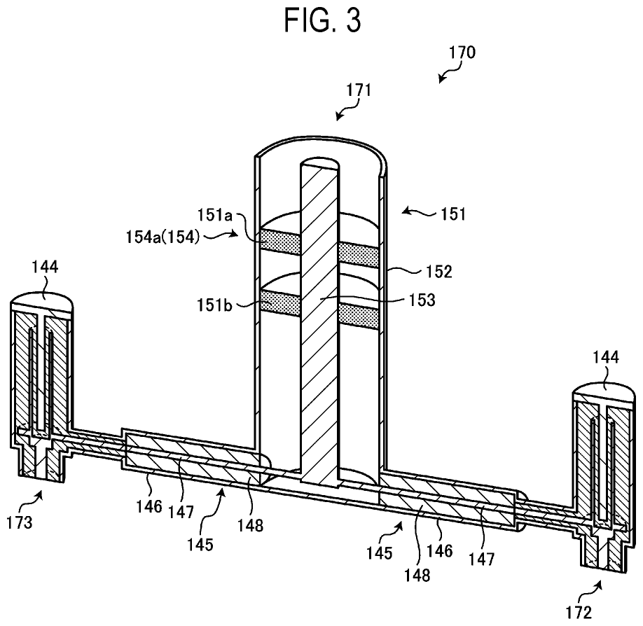

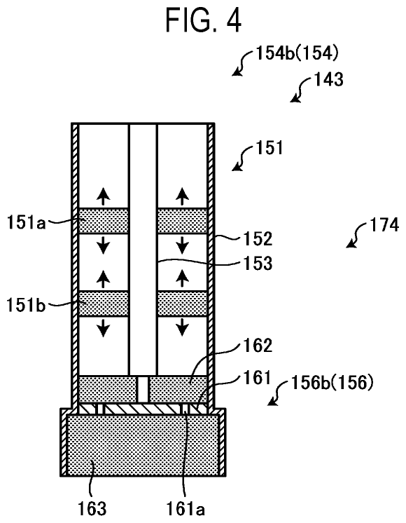

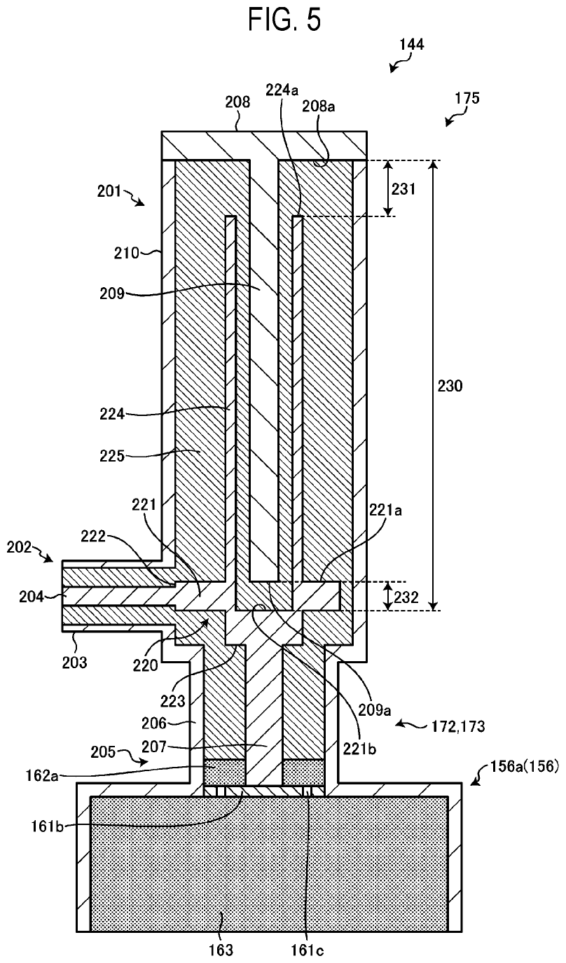

Next, the antenna unit 140 will be described in detail with reference to FIGS. 2 to 5. FIG. 2 is a perspective view illustrating an example of the antenna unit in the first embodiment. FIG. 3 is a cross-sectional view illustrating an example of a distributor taken along line A-A in FIG. 2. FIG. 4 is a diagram schematically illustrating an example of a microwave radiator in the first embodiment. FIG. 5 is a cross-sectional view illustrating an example of a vicinity of an output terminal in the first embodiment. As shown in FIG. 2, the antenna unit 140 has the microwave radiator 143, which is arranged at the center of the ceiling wall portion 111, and three distributors 170.

As shown in FIGS. 2 and 3, the distributor 170 includes two filters 144 and one tuner 154a. In FIG. 2, the tuner 154a of the distributor 170 and a tuner 154b of the microwave radiator 143 are simply represented as a tuner 154. A coaxial waveguide 145 is connected between an output side of the tuner 154a and an input side of each of the filters 144. An outer conductor 146 and an inner conductor 147 of the coaxial waveguide 145 are connected to an outer conductor 152 and an inner conductor 153 of the tuner 154a, respectively. Further, the outer conductor 146 and the inner conductor 147 are respectively connected to an outer cylinder 203 and an inner shaft 204 of an input port 202 of the filter 144, which will be described later. An input side of the tuner 154a of the distributor 170, that is, a power supply terminal 171 of the distributor 170, is connected to the amplifier 142. Output sides of the filters 144, that is, output terminals 172 and 173, are each connected to an antenna portion 156a. A dielectric 148 may be arranged between the outer conductor 146 and the inner conductor 147 of the coaxial waveguide 145 as shown in FIG. 3 or may not be arranged.

As shown in FIG. 4, the microwave radiator 143 has the tuner 154b. An input side of the tuner 154b of the microwave radiator 143 is connected to the amplifiers 142. An output side of the tuner 154b of the microwave radiator 143 is connected to the antenna portion 156b. In the following description, the tuners 154a and 154b may be collectively referred to as the tuner 154, and the antenna portions 156a and 156b may be collectively referred to as the antenna portion 156.

The tuner 154 constitutes a slug tuner. As shown in FIGS. 3 and 4, the tuner 154 includes a coaxial tube 151 having a microwave transmission path, slugs 151a and 151b, an actuator, and a tuner controller, between an outer conductor 152 and an inner conductor 153. The slugs 151a and 151b are two slugs arranged in the coaxial tube 151. The slugs 151a and 151b are driven by the actuator controlled by the tuner controller. The slugs 151a and 151b are plate-shaped and ring-shaped and are made of a dielectric material such as ceramics. The slugs 151a and 151b are arranged between the outer conductor 152 and the inner conductor 153 of the coaxial tube 151. The positions of the slugs 151a and 151b are adjusted so that impedance at a terminal end is 50Ω. In other words, the tuner 154 is an example of a matcher. A matching frequency in the tuner 154b of the microwave radiator 143 is different from a resonance frequency of the filter 144 of the distributor 170, which will be described later.

As shown in FIGS. 4 and 5, the antenna portions 156a and 156b are provided at the output terminals 172 and 173 and at a lower end of the coaxial tube 151 of the microwave radiator 143, respectively. The antenna portion 156b includes a disc-shaped planar antenna 161 connected to a lower end of the inner conductor 153, a wavelength shortening member 162 arranged on the upper surface of the planar antenna 161, and a microwave transmission plate 163 arranged on the lower surface of the planar antenna 161. The antenna portion 156a includes a planar antenna 161b, a wavelength shortening member 162a, and the microwave transmission plate 163. The planar antenna 161b has a disc shape and is connected to an inner shaft 207 of an output port 205 of the output terminals 172 and 173, which will be described later. The wavelength shortening member 162a is arranged on the upper surface of the planar antenna 161b. The microwave transmission plate 163 is arranged on the lower surface of the planar antenna 161b. The microwave transmission plate 163 is fitted into the ceiling wall portion 111, and the lower surface of the microwave transmission plate 163 is exposed to the internal space of the processing container 101. It is assumed that the diameters of the microwave transmission plates 163 in the antenna portions 156a and 156b are the same, and the thicknesses of the microwave transmission plates 163 in the antenna portions 156a and 156b are the same. The planar antennas 161 and 161b have slots 161a and 161c formed therethrough, respectively. The shapes of the slots 161a and 161c are appropriately configured so that microwaves are efficiently radiated. A dielectric may be inserted into the slots 161a and 161c.

The wavelength shortening members 162 and 162a are made of materials having a dielectric constant greater than that of vacuum. The phase of the microwaves may be adjusted by the thicknesses of the wavelength shortening members 162 and 162a, and thus, the radiation energy of the microwaves may be maximized. The microwave transmission plate 163 is also made of a dielectric and has a shape that allows the microwaves to be efficiently radiated in TE mode. The microwaves transmitted through the microwave transmission plate 163 generate plasma in the space inside the processing container 101. As materials constituting the wavelength shortening members 162 and 162a and the microwave transmission plate 163, for example, quartz or a ceramic, a fluorine-based resin such as a polytetrafluoroethylene resin, and a polyimide resin may be used.

In the first embodiment, the microwave transmission plate 163 is arranged so as to form a uniform hexagonal close-packed arrangement in the ceiling wall portion 111. In this case, if the antenna portion 156 including the microwave transmission plate 163 is an example of a cell, a cell 174, which is a set of the antenna portion 156b and the microwave radiator 143 including the tuner 154b, is an example of an inner cell arranged at the center of the ceiling wall portion 111. Further, a cell 175, which is a set of the filter 144 and the antenna portion 156a including the microwave transmission plate 163, is an example of a plurality of outer cells arranged in the ceiling wall portion 111 so as to surround the vicinity of the inner cell.

As shown in FIG. 5, the filter 144 has a housing 201. The housing 201 is made of a conductor such as aluminum or copper. Further, the housing 201 includes an input port 202 and an output port 205. The output port 205 corresponds to the output terminals 172 and 173. In this embodiment, a side connected to the coaxial waveguide 145 on the output side of the tuner 154a of the distributor 170 is defined as the input port 202, and a side connected to the antenna portion 156a is defined as the output port 205, based on a flow direction of electromagnetic waves supplied from the microwave output portion 130. Connection destinations of the input port 202 and the output port 205 may be switched.

The input port 202 and the output port 205 are formed by outer cylinders (outer conductors) 203 and 206 and inner shafts (inner conductors) 204 and 207, respectively. That is, the input port 202 and the output port 205 have a coaxial structure. The housing 201 is electrically connected to the outer cylinders 203 and 206 and is grounded together with the grounded processing container 101 via the coaxial waveguide 145 connected to the input port 202 or via a frame in which the antenna unit 140 is installed. The housing 201 has a cylindrical shape, and the input port 202 is formed on a side surface 210 of the cylinder. The housing 201 may have a cylindrical shape with a square cross section. Further, in the housing 201, the output port 205 is formed at an end of the cylinder on the side on which the input port 202 is formed, and another end 208 is formed in a disc shape so as to close the cylinder. Furthermore, a ground fin 209 formed of a conductor such as aluminum or copper and protruding into the housing 201 is connected to the end 208. The ground fin 209 has, for example, a cylindrical shape.

A power supply fin 224 formed to surround the ground fin 209 is provided inside the housing 201. The ground fin 209 and the power supply fin 224 are arranged coaxially. The power supply fin 224 is made of a conductor such as aluminum or copper and has a cylindrical shape with one end closed by a base portion 221. That is, the power supply fin 224 is a monopole antenna of a cylindrical shape. In other words, the ground fin 209, in the cross section shown in FIG. 5, is provided to protrude into the housing 201 so as to be inserted between fins of the power supply fins 224. The base portion 221 is disc-shaped, and the center of the base portion 221 is convex so as to be offset toward the output port 205. The inner shaft 204 is connected to a side surface 222 of the base portion 221. The inner shaft 207 is connected to a bottom surface 223 of the convex portion of the base portion 221. That is, a power supply line 220 insulated from the housing 201 is formed by the inner shaft (input side conductor) 204 of the input port 202, the inner shaft (output side conductor) 207 of the output port 205, and the power supply fin 224. That is, in the filter 144, the power supply line 220 formed by the inner shaft 204, the power supply fin 224, and the inner shaft 207 is arranged at right angles.

A dielectric 225 is provided between the housing 201 and the power supply line 220. That is, the dielectric 225 is filled between the ground fin 209 and the power supply fin 224, between the power supply fin 224 and the side surface 210 of the cylinder, and between a tip 224a of the power supply fin 224 and the end 208. Similarly, the dielectric 225 is filled between the outer cylinder 203 and the inner shaft 204 of the input port 202 and between the outer cylinder 206 and the inner shaft 207 of the output port 205. The dielectric 225 may be, for example, polytetrafluoroethylene (PTFE). Further, the dielectric 225 may be omitted.

In addition, a space corresponding to a section 230 in FIG. 5, i.e., a space between the housing 201, the ground fin 209, and the power supply fin 224, from a surface 221a of the outer perimeter of the base portion 221 of the power supply fin 224 to a central surface 221b of the base portion 221, forms a standing wave region. That is, the filter 144 is an example of a resonator having a specific resonance frequency. Further, the filter 144 is an example of a band-pass filter using a three-dimensional circuit. A section 231, which is a gap between the tip 224a of the power supply fin 224 and an inner surface 208a of the end 208, and a section 232, which is a gap between a tip 209a of the ground fin 209 and the surface 221b of the power supply fin 224, are determined in consideration of, for example, a dielectric breakdown voltage of the dielectric 225. For example, when the dielectric 225 is PTFE, the sections 231 and 232 are determined using a value of 1 kV/mm obtained by considering a safety factor of about 20 times from 19 kV/mm, which is the dielectric breakdown voltage of PTFE. The filter 144 may have a low height (shorter vertical length) by increasing the number of the ground fins 209 and the power supply fins 224. Further, the filter 144 may be configured so that the ground fin 209 is movable in a vertical direction (a longitudinal direction of the filter 144) to vary the resonance frequency.

The antenna portion 156a is provided at the output port 205 (output terminals 172 and 173) of the filter 144. In addition, the antenna portion 156a provided at the output port 205 has the same function as the antenna portion 156b provided at the lower end of the coaxial tube 151 of the microwave radiator 143, as described above.

### [Power Distribution Ratio]

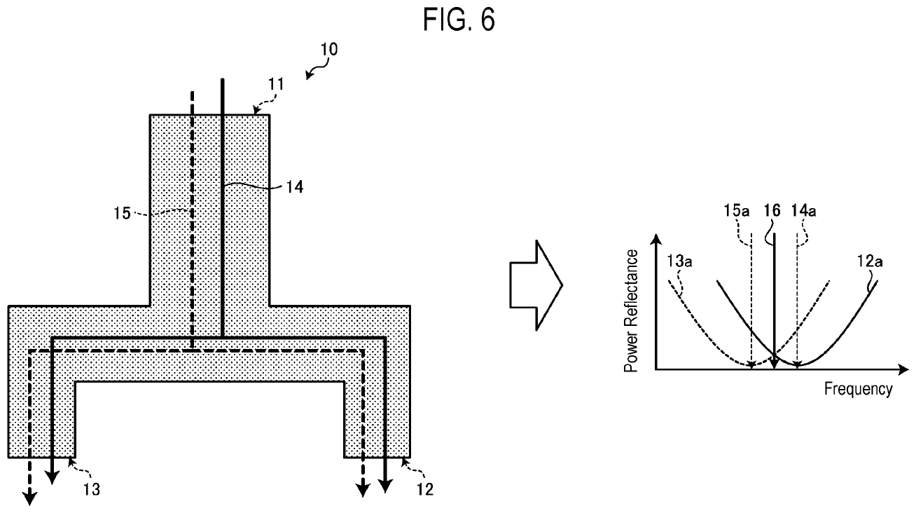

Next, a method of controlling a power distribution ratio will be described with reference to FIG. 6. FIG. 6 is a diagram illustrating an example of a method of controlling a power distribution ratio. A case in which a distributor 10 shown in FIG. 6 distributes, like the distributor 170, radio-frequency power input from one power supply terminal 11 to two output terminals 12 and 13 is schematically illustrated. In FIG. 6, a tuner located at the power supply terminal 11 is omitted.

In the distributor 10, a transmission path from the power supply terminal 11 towards the output terminal 12 and a transmission path from the power supply terminal 11 towards the output terminal 13 have different power transmission characteristics. That is, in the distributor 10, a power reflectance 12a and a resonance frequency 14a, which are frequency characteristics of the transmission path towards the output terminal 12, and a power reflectance 13a and a resonance frequency 15a, which are frequency characteristics of the transmission path towards the output terminal 13, are different. In this case, in a radio-frequency power 14 of the same frequency as the resonance frequency 14a, the power reflectance 12a at the output terminal 12 of the resonance frequency 14a is low and the power reflectance 13a at the output terminal 13 of the resonance frequency 15a is high. In other words, the distribution ratio of the radio-frequency power 14 towards the output terminal 12 becomes high. On the other hand, in radio-frequency power 15 of the same frequency as the resonance frequency 15a, the power reflectance 13a at the output terminal 13 of the resonance frequency 15a is low and the power reflectance 12a at the output terminal 12 of the resonance frequency 14a is high. In other words, the distribution ratio of the radio-frequency power 15 towards the output terminal 13 becomes high. Further, in radio-frequency power of a frequency 16 corresponding to the middle of the resonance frequency 14a and the resonance frequency 15a, a power reflectance 12a at the output terminal 12 and a power reflectance 13a at the output terminal 13 are equal, and power is equally distributed to the output terminal 12 and the output terminal 13. That is, by modulating the frequency of radio-frequency power output from the microwave output portion, a power distribution ratio may be controlled without providing a mechanical drive portion.

### [Simulation Results]

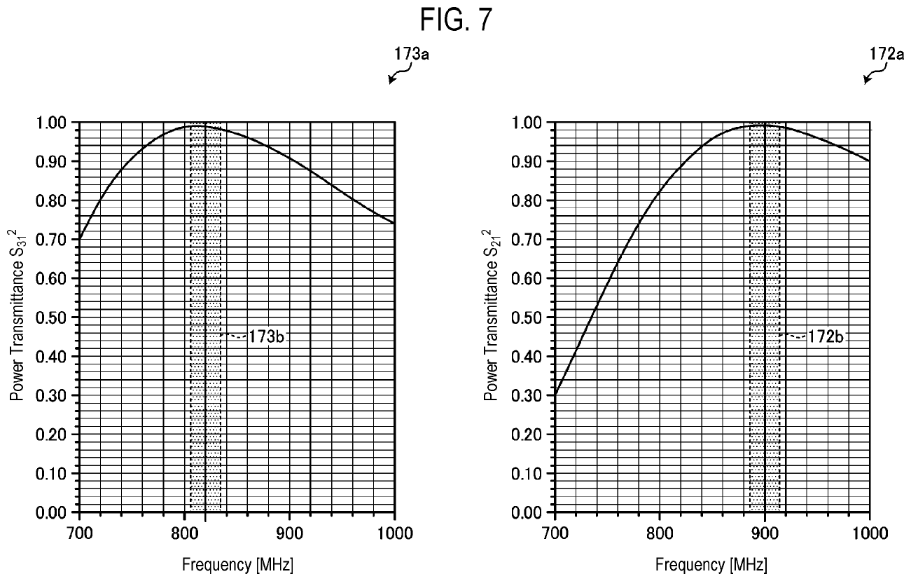

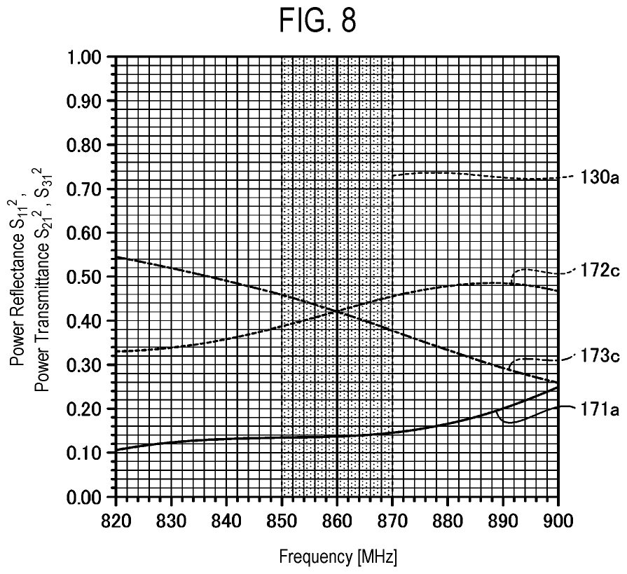

Next, simulation results of frequency characteristics of the distributor 170 will be described with reference to FIGS. 7 and 8. FIG. 7 is a diagram illustrating an example of frequency characteristics of a single filter in the first embodiment. Graphs 172a and 173a shown in FIG. 7 represent frequency characteristics of each filter 144 of the output terminals 172 and 173 of the distributor 170, respectively. The arrangement of the graphs 172a and 173a corresponds to the output terminals 172 and 173 in FIG. 3. As shown in the graph 172a, the filter 144 of the output terminal 172 has a power transmittance S₂₁² of approximately 1.00 at a resonance frequency of 900 MHz. Further, the filter 144 of the output terminal 172 is a band-pass filter with a band width 172b (a width of 30 MHz from 885 MHz to 915 MHz). On the other hand, as shown in the graph 173a, the filter 144 of the output terminal 173 has a power transmittance S₃₁² of about 1.00 at a resonance frequency of 820 MHz. Further, the filter 144 of the output terminal 173 is a band-pass filter with a band width 173b (a width of 30 MHz from 805 MHz to 835 MHz).

FIG. 8 is a diagram illustrating an example of frequency characteristics of a distributor in the first embodiment. A graph 171a shown in FIG. 8 represents a frequency characteristic of a power reflectance S₁₁² at the power supply terminal 171 of the distributor 170. A graph 172c represents a frequency characteristic of a power transmittance S₂₁² at the output terminal 172 of the distributor 170. A graph 173c represents a frequency characteristic of a power transmittance S₃₁² at the output terminal 173 of the distributor 170. The example of FIG. 8 considers that the range of frequency modulation in the microwave output portion 130 is set to a range 130a. Here, a center frequency f of radio-frequency power uses 860 MHz, which is an intermediate frequency of a resonance frequency of 900 MHz of the filter 144 of the output terminal 172 and a resonance frequency of 820 MHz of the filter 144 of the output terminal 173. Similarly to a second embodiment described later, resonance frequencies of the respective filters 144 of cells 175 may all be different frequencies.

First, when a radio-frequency power of 1,000 W is input from the microwave output portion 130 without impedance matching, radio-frequency powers output from the output terminals 172 and 173 at a center frequency of 860 MHz are calculated by the following equations (1) and (2). In the case of no impedance matching, a radio-frequency power of the power reflectance S₁₁² corresponding to the graph 171a is reflected toward the microwave output portion 130.

$$Output of output terminal 172 = 1 , 000 \times {S}_{21}^{2} = 1 , 000 \times 0.43 = 430 W \qquad ( 1 )$$

$$Output of output terminal 173 = 1 , 000 \times {S}_{31}^{2} = 1 , 000 \times 0.43 = 430 W \qquad ( 2 )$$

At a lower limit frequency of 850 MHz in the range 130a of frequency modulation, the radio-frequency powers output from the output terminals 172 and 173 are expressed by the following equations (3) and (4).

$$Output of output terminal 172 = 1 , 000 \times {S}_{21}^{2} = 1 , 000 \times 0.38 = 380 W \qquad ( 3 )$$

$$Output of output terminal 173 = 1 , 000 \times {S}_{31}^{2} = 1 , 000 \times 0.47 = 470 W \qquad ( 4 )$$

At an upper limit frequency of 870 MHz in the range 130a of frequency modulation, the radio-frequency powers output from the output terminals 172 and 173 are expressed by the following equations (5) and (6).

$$Output of output terminal 172 = 1 , 000 \times {S}_{21}^{2} = 1 , 000 \times 0.46 = 460 W \qquad ( 5 )$$

$$Output of output terminal 173 = 1 , 000 \times {S}_{31}^{2} = 1 , 000 \times 0.38 = 380 W \qquad ( 6 )$$

Next, when a radio-frequency power of 1,000 W is input from the microwave output portion 130 with impedance matching, a power ratio of the output terminals 172 and 173 becomes power transmittance S₂₁²: power transmittance S₃₁². Therefore, the power ratio of the output terminals and the radio-frequency powers output from the output terminals 172 and 173 at a center frequency of 860 MHz are expressed by the following equations (7) to (9). In the case of impedance matching, a radio-frequency power of the power reflectance S₁₁² corresponding to the graph 171a is not reflected toward the microwave output portion 130.

$$\begin{matrix}Power ratio ) & \\ Output terminal 172 : Output terminal 173 = 1 : 1 & ( 7 )\end{matrix}$$

$$Output of output terminal 172 = 1 , 000 \times {S}_{21}^{2} / ( {S}_{21}^{2} + {S}_{31}^{2} ) = 1 , 000 \times 1 / 2 = 500 W \qquad ( 8 )$$

$$Output of output terminal 173 = 1 , 000 \times {S}_{31}^{2} / ( {S}_{21}^{2} + {S}_{31}^{2} ) = 1 , 000 \times 1 / 2 = 500 W \qquad ( 9 )$$

At a lower limit frequency of 850 MHz in the range 130a of frequency modulation, the power ratio of the output terminals 172 and 173 and the radio-frequency powers output from the output terminals 172 and 173 are expressed by the following equations (10) to (12).

$$\begin{matrix}Power ratio ) & \\ Output terminal 172 : Output terminal 173 = 38 : 47 & ( 10 )\end{matrix}$$

$$Output of output terminal 172 = 1 , 000 \times {S}_{21}^{2} / ( {S}_{21}^{2} + {S}_{31}^{2} ) = 1 , 000 \times 38 / ( 47 + 38 ) = 447 W \qquad ( 11 )$$

$$Output of output terminal 173 = 1 , 000 \times {S}_{31}^{2} / ( {S}_{21}^{2} + {S}_{31}^{2} ) = 1 , 000 \times 47 / ( 47 + 38 ) = 553 W \qquad ( 12 )$$

At an upper limit frequency of 870 MHz in the range 130a of frequency modulation, the power ratio of the output terminals 172 and 173 and the radio-frequency powers output from the output terminals 172 and 173 are expressed by the following equations (13) to (15).

$$\begin{matrix}Power ratio ) & \\ Output terminal 172 : Output terminal 173 = 46 : 38 & ( 13 )\end{matrix}$$

$$Output of output terminal 172 = 1 , 000 \times {S}_{21}^{2} / ( {S}_{21}^{2} + {S}_{31}^{2} ) = 1 , 000 \times 46 / ( 38 + 46 ) = 548 W \qquad ( 14 )$$

$$Output of output terminal 173 = 1 , 000 \times {S}_{31}^{2} / ( {S}_{21}^{2} + {S}_{31}^{2} ) = 1 , 000 \times 38 / ( 38 + 46 ) = 452 W \qquad ( 15 )$$

In this way, the distributor 170 may control the distribution ratio of the output terminals 172 and 173 according to the frequency of the radio-frequency power input from the microwave output portion 130. That is, the distributor 170 may vary the distribution ratio of the input power. Further, the distributor may be miniaturized using the filter 144 relative to a conventional distributor.

### Second Embodiment

While the radio-frequency power is divided into two by the distributor 170 in the first embodiment described above, the radio-frequency power may be divided into three or more, and an embodiment in this case will be described as the second embodiment. Since a plasma processing apparatus in the second embodiment is the same as the above-described first embodiment except for the configuration of the antenna unit 140 and the ceiling wall portion 111 corresponding to the antenna unit 140, a description of redundant configurations and operations will be omitted. In addition, the same components of the antenna unit 140 as those in the first embodiment are denoted by the same reference numerals, and a description of redundant configurations and operations will be omitted.

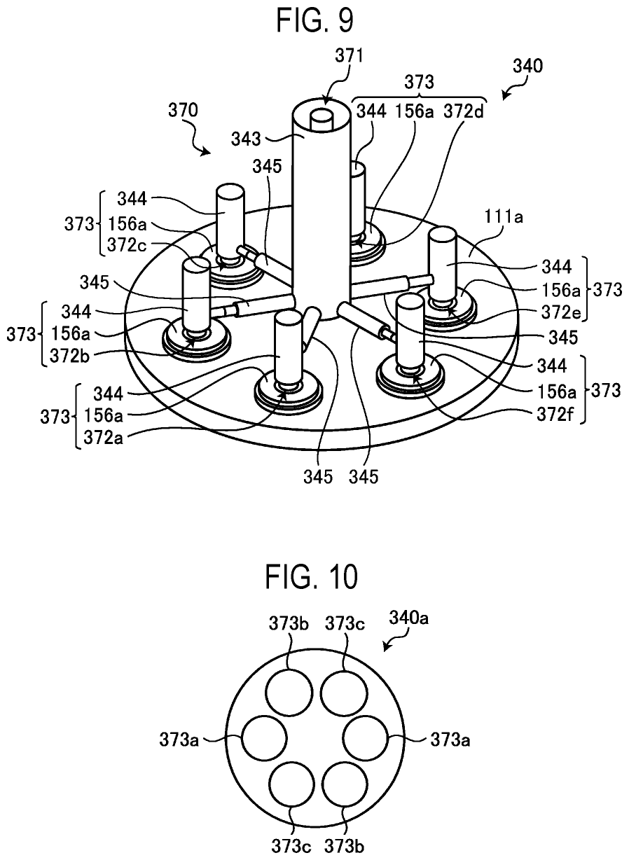

FIG. 9 is a perspective view illustrating an example of an antenna unit in a second embodiment. As shown in FIG. 9, an antenna unit 340 includes a distributor 370. The distributor 370 has six filters 344 and one tuner 343. An output side of the tuner 343 and an input side of the filter 344 are connected by a coaxial waveguide 345. Since the configurations of the tuner 343, the coaxial waveguide 345, and the filter 344 are the same as those of the tuner 154, the coaxial waveguide 145, and the filter 144 of the first embodiment, a description thereof will be omitted. An input side of the tuner 343 of the distributor 370, i.e., a power supply terminal 371 of the distributor 370, is connected to the amplifier 142. Each output side of the filters 344, i.e., output terminals 372a to 372f, is connected to the antenna portion 156a. In addition, in the following description, when the output terminals 372a to 372f are not distinguished from each other, they are simply referred to as an output terminal 372.

In the distributor 370, assuming that a set of the antenna portion 156a including the microwave transmission plate 163, the filter 344, and the output terminal 372 is a cell 373, six cells 373 are arranged on the same circumference in a ceiling wall portion 111a. The respective filters 344 corresponding to the output terminals 372a to 372f have different resonance frequencies. For example, the output terminals 372a to 372f have sequential resonance frequencies from 840 MHz to 865 MHz at an interval of 5 MHz. The distributor 370 modulates a frequency of radio-frequency power output from the microwave output portion 130 to a resonance frequency of each of the filters 344 corresponding to the output terminals 372a to 372f, thereby adjusting a distribution ratio to each of the output terminals 372a to 372f. Further, it is possible to suppress interference of radio-frequency power by setting resonance frequencies of the filters 344 of adjacent cells 373 to different frequencies. That is, the distributor 370 may independently control distribution of plasma density in each of the six cells 373. Even in the first embodiment, all of the resonance frequencies of the filters 144 of the three distributors 170 may be set to different frequencies, for example, from 840 MHz to 865 MHz at an interval of 5 MHz.

Next, variations in combinations of resonance frequencies of filters in the second embodiment will be described with reference to FIGS. 10 to 12. FIG. 10 is a diagram schematically illustrating an example of a combination of resonance frequencies of filters in the second embodiment. In an antenna unit 340a shown in FIG. 10, the resonant frequency of the filter 344 of the output terminal 372 is set to be the same frequency with respect to each set of cells 373a to 373c located opposite each other with the center of the ceiling wall portion 111a as an axis. Even in this case, resonance frequencies of the respective filters 344 of adjacent cells 373a to 373c are different frequencies. Further, in combination with the first embodiment, six cells 373a to 373c are arranged at equal intervals on the circumference, and the distributor 170 may be provided for each of three sets of adjacent cells 373a and 373b, cells 373c and 373a, and cells 373b and 373c. That is, the distributor 170 may include three systems each connected to the microwave output portion 130. That is, in a set of adjacent cells 373, the resonant frequencies (frequency characteristics) of the filters 344 are different.

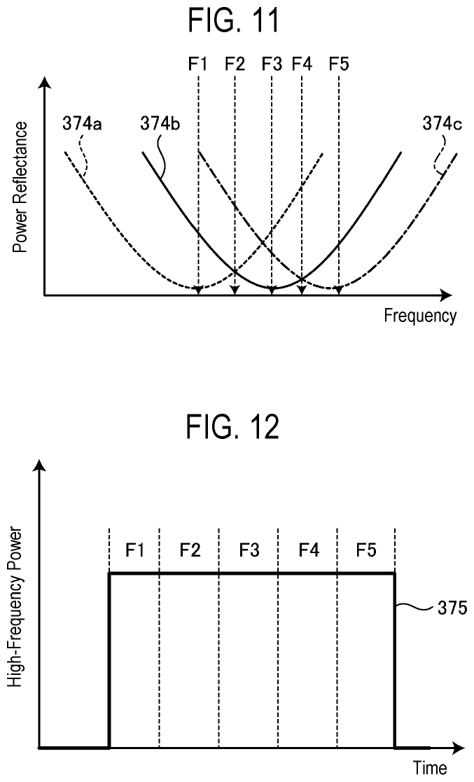

FIG. 11 is a diagram illustrating an example of a combination of a resonance frequency of a filter and a frequency of radio-frequency power in the second embodiment. Graphs 374a to 374c shown in FIG. 11 express resonance frequencies of the respective filters 344 corresponding to the cells 373a to 373c shown in FIG. 10 as power reflectance. In the example of FIG. 11, the frequency of radio-frequency power output from the microwave output portion 130 is modulated to frequencies F1 to F5 to control a distribution ratio of radio-frequency power in the cells 373a to 373c. For example, when radio-frequency power of a frequency F1 is output from the microwave output portion 130, power reflectance at the frequency F1 increases in order of a graph 374a, a graph 374b, and a graph 374c. In other words, the distribution ratio of the radio-frequency power decreases in order of the cell 373a, the cell 373b, and the cell 373c.

For example, when radio-frequency power of a frequency F2 is output from the microwave output portion 130, power reflectance at the frequency F2 is the same in the graph 374a and the graph 374b and is higher in the graph 374c than in the graphs 374a and 374b. That is, the distribution ratio of the radio-frequency is the same for the cells 373a and 373b and is smaller for the cell 373c than for the cells 373a and 373b.

For example, when radio-frequency power of a frequency F3 is output from the microwave output portion 130, power reflectance at the frequency F3 increases in order of the graph 374b, the graph 374c, and the graph 374a. That is, the distribution ratio of the radio-frequency power decreases in order of the graph 374b, the graph 374c, and the graph 374a.

For example, when radio-frequency power of a frequency F4 is output from the microwave output portion 130, power reflectance at the frequency F4 is the same in the graph 374b and the graph 374c and is higher in the graph 374a than in the graphs 374b and 374c. That is, the distribution ratio of the radio-frequency power is the same for the cells 373b and 373c and is smaller for the cell 373a than for the cells 373b and 373c.

For example, when radio-frequency power of a frequency F5 is output from the microwave output portion 130, power reflectance at the frequency F5 increases in order of the graph 374c, the graph 374b, and the graph 374a. That is, a distribution ratio of the radio-frequency power decreases in order of the cell 373c, the cell 373b, and the cell 373a.

FIG. 12 is a timing chart illustrating an example of change in a frequency of radio-frequency power in the second embodiment. A graph 375 shown in FIG. 12 represents one cycle of changes over output time in radio-frequency powers corresponding to the frequencies F1 to F5 shown in FIG. 11. In the graph 375, while the radio-frequency powers of the frequencies F1 to F5 are set to the same value, the output of the radio-frequency power from the microwave output portion 130 may be changed as the frequencies F1 to F5 change. In addition, in the graph 375, while output times of frequencies F1 to F5 are the same, the output times of frequencies F1 to F5 may be arbitrarily changed, for example, by lengthening the output time of the frequency F1 and shortening the output time of the frequency F2. In the example of FIG. 12, a distribution ratio of radio-frequency power in the cells 373a to 373c may be controlled by changing the output and output time of the radio-frequency power output from the microwave output portion 130.

While each of the number of cells 175 and the number of cells 373 is six in each embodiment described above, the number is not limited thereto. For example, when the distributor 170 divided into two is used as n systems, the number of cells 175 may be 2n (where n is an integer of 1 or more). Further, for example, when a distributor divided into m (where m is an integer of 3 or more) is used, the number of cells 373 may be m.

Furthermore, in the first embodiment described above, while the cell 174 is arranged at the center of the ceiling wall portion 111, the arrangement of the cell 174 is not limited thereto. For example, the cell 174 may be omitted and only the cell 175, which is an outer cell, may be arranged.

As described above, according to each embodiment, distributors (the distributors 170 and 370) distribute electromagnetic waves to a plurality of output terminals (the output terminals 172, 173, and 372a to 372f), and include power supply terminals (the power supply terminals 171 and 371) configured to be electrically connected to a radio-frequency power source (the microwave output portion 130) capable of varying frequency and a plurality of filters (the filters 144 and 344) provided respectively at a plurality of output terminals to which the electromagnetic waves input to the power supply terminals are distributed. The filters are configured to have different frequency characteristics. As a result, a power distribution ratio may be varied.

Further, according to each embodiment, each filter includes a housing 201 (which includes the input port 202 and the output port 205 having inner shafts (the inner shafts 204 and 207) and outer cylinders (the outer cylinders 203 and 206) and is configured to have the same potential as the outer cylinders of the input port 202 and the output port 205), the power supply fin 224 (which connects the inner shaft 204 of the input port 202 and the inner shaft 207 of the output port 205 and is provided within the housing 201), and the ground fin 209 (which is connected to the housing 201 at the same potential and is provided to protrude into the housing 201 so as to be inserted between fins of the power supply fin 224). As a result, the filter can be miniaturized.

According to the first embodiment, each of the number of output terminals (the output terminals 172 and 173) of the distributor and the number of filters 144 of the distributor is two. As a result, a power distribution ratio may be varied in the output terminals divided into two.

Further, according to the second embodiment, each of the number of output terminals (the output terminals 372a to 372f) of the distributor and the number of filters 344 of the distributor is three or more. As a result, the power distribution ratio may be varied in the output terminals divided into three or more.

Further, according to each embodiment, paths (the coaxial waveguides 145 and 345) between power supply terminals (the power supply terminals 171 and 371) and filters (the filters 144 and 344) are branched into branches in a middle, and matchers (the tuners 154 and 343) that match electromagnetic waves are provided between the power supply terminals and the branches. As a result, reflection of the electromagnetic waves toward the radio-frequency power source (the microwave output portion 130) may be suppressed.

Further, according to each embodiment, the power of the electromagnetic waves output from each of a plurality of output terminals is distributed according to the frequency characteristic. As a result, the power distribution ratio may be varied by frequency modulation.

Further, according to each embodiment, the plasma processing apparatus 100 includes the processing container 101, a radio-frequency power source (the microwave output portion 130) capable of varying frequency, distributors (the distributor 170 and 370) that distribute electromagnetic waves output by the radio-frequency power source to a plurality of output terminals (the output terminals 172, 173, and 372a to 372f), slot antennas (the planar antennas 161 and 161b) connected to the output terminals, and a transmission window (the microwave transmission plate 163) configured to transmit electromagnetic waves radiated from the slot antennas and supply the electromagnetic waves into the processing container 101. The distributor includes power supply terminals (the power supply terminals 171 and 371) configured to be electrically connected to the radio-frequency power source and a plurality of filters (the filters 144 and 344) provided respectively at a plurality of output terminals (the output terminals 172, 173, and 372a to 372f) to which the electromagnetic waves input to the power supply terminals are distributed. The filters are configured to have different frequency characteristics. As a result, the power distribution ratio can be varied. In addition, the distribution of plasma density may be controlled.

Further, according to each embodiment, a plurality of cells (cells 175 and 373), each of which is a set of the filter, the output terminal, the slot antenna, and the transmission window, is arranged on the same circumference on the upper surface (the ceiling wall portions 111 and 111a) of the processing container 101. As a result, the distribution of plasma density may be controlled.

Further, according to each embodiment, the plurality of cells 175 is arranged as 2n cells at equal intervals on the circumference. The distributor 170 distributes the electromagnetic waves to two of the cells 175 and includes n systems each connected to the radio-frequency power source. The frequency characteristics of the filters 144 of the respective cells 175 are different from each other. As a result, the distribution of plasma density may be independently controlled in each of the 2n cells 175.

Further, according to the first embodiment, a cell, which is a set of the slot antenna and the transmission window, includes an inner cell (the cell 174) including a matcher (the tuners 154a and 154b) for matching the electromagnetic waves and arranged at a center of an upper surface of the processing container 101, and a plurality of outer cells (the cells 175) including the filter 144 and the output terminal and arranged on the upper surface (the ceiling wall portion 111) of the processing container 101 to surround a vicinity of the inner cell. As a result, the distribution of plasma density may be independently controlled in each of the inner cell and the outer cells.

Further, according to the first embodiment, the plurality of outer cells is arranged as 2n outer cells at equal intervals on the same circumference. The distributor 170 distributes the electromagnetic waves to two of the outer cells and includes n systems each connected to the radio-frequency power source. The frequency characteristics of the filters 144 are different in respective outer cells belonging to the same system. As a result, the distribution of plasma density may be independently controlled in each of the inner cell and the outer cells. Further, the filters 144 having the same frequency characteristics may be used between different systems.

Further, according to the first embodiment, there are two types of frequency characteristics within the same system, and two types of frequencies are shared between different systems. As a result, the filters 144 having the same frequency characteristics may be used between different systems.

Further, according to the second embodiment, the plurality of outer cells (the cells 373) is arranged as n output cells at equal intervals on the same circumference. The distributor 370 distributes the electromagnetic waves to n outer cells of the outer cells, and the frequency characteristics of the filters 344 are different in respective outer cells adjacent to each other. As a result, the distribution of plasma may be independently controlled in each of the n cells 373.

Further, according to the second embodiment, n is 3 or more, there are three or more types of frequency characteristics, and the radio-frequency power source changes frequencies at a predetermined period. As a result, the distribution of plasma density may be independently controlled in each of the three or more cells 373 according to the predetermined period.

Further, according to the second embodiment, n is 6, there are three types of frequency characteristics, and the frequency characteristics of the filters 344 are identical in the outer cells positioned in a point-symmetrical position about a center point of the upper surface (the ceiling wall portion 111a) of the processing container 101, among the plurality of outer cells. As a result, the distribution of plasma density may be independently controlled in each of the three or more cells 373 according to a predetermined period. In addition, the cells 373 positioned in a point-symmetrical position may use the filters 344 having the same frequency characteristics.

Further, according to the second embodiment, the radio-frequency power source changes a time for maintaining each frequency in the changed frequencies. As a result, the distribution of plasma density may be controlled depending on the times during which the frequencies are maintained.

Further, according to the first embodiment, frequency characteristics of the matcher in the inner cell are different from frequency characteristics of the filters 144 in the respective outer cells. As a result, the distribution of plasma density may be independently controlled in each of the inner cell and the outer cell.

It is to be noted that the embodiments disclosed herein are exemplary in all respects and are not restrictive. The above-described embodiments may be omitted, replaced, and/or modified in various forms without departing from the scope and spirit of the appended claims.

Furthermore, while each of the above-described embodiments has been described based on the plasma processing apparatus 100 that directly generates plasma in the processing space within the processing container 101, embodiments are not limited thereto. For example, embodiments may be applied to a remote plasma processing apparatus having a separate plasma generation room within the chamber.

Additionally, the present disclosure may also have the following configuration.

(1) A distributor for distributing electromagnetic waves to a plurality of output terminals includes a power supply terminal configured to be electrically connected to a radio-frequency power source capable of varying frequency, and a plurality of filters provided respectively at the output terminals to which the electromagnetic waves input to the power supply terminal are distributed. The filters may be configured to have different frequency characteristics.

(2) In the distributor of (1), each of the filters includes a housing including an input port and an output port each having an inner shaft and an outer cylinder and configured to have a same potential as the outer cylinders of the input port and the output port, a power supply fin connecting the inner shaft of the input port and the inner shaft of the output port and provided within the housing, and a ground fin connected to the housing at the same potential and provided to protrude into the housing so as to be inserted between fins of the power supply fin.

(3) In the distributor of (2), each of the number of the output terminals and the number of the filters is 2.

(4) In the distributor of (1) or (2), each of the number of the output terminals and the number of the filters is 3 or more.

(5) In the distributor of any one of (1) to (4), a path between the power supply terminal and each of the filters is branched into branches in a middle, and a matcher configured to match the electromagnetic waves is provided between the power supply terminal and each of the branches.

(6) In the distributor of any one of (1) to (5), power of the electromagnetic waves output from each of the output terminals is distributed according to the frequency characteristics.

(7) A plasma processing apparatus is provided. The plasma processing apparatus includes a processing container, a radio-frequency power source capable of varying frequency, a distributor configured to distribute electromagnetic wave output by the radio-frequency power source to a plurality of output terminals, a slot antenna connected to each of the output terminals, and a transmission window configured to transmit the electromagnetic wave radiated from the slot antenna and supply the electromagnetic wave into the processing container. The distributor includes a power supply terminal configured to be electrically connected to the radio-frequency power source, and a plurality of filters provided respectively at the output terminals to which the electromagnetic wave input to the power supply terminal are distributed. The filters are configured to have different frequency characteristics.

(8) In the plasma processing apparatus of (7), a plurality of cells, each of which is a set of the filter, the output terminal, the slot antenna, and the transmission window, is arranged on a same circumference on an upper surface of the processing container.

(9) In the plasma processing apparatus of (8), the plurality of cells is arranged as 2n cells at equal intervals on the circumference, the distributor distributes the electromagnetic wave to two of the cells and includes n systems each connected to the radio-frequency power source, and the frequency characteristics of the filters are different in the respective cells.

(10) In the plasma processing apparatus of (7), a cell, which is a set of the slot antenna and the transmission window, includes an inner cell including a matcher for matching the electromagnetic wave and arranged at a center of an upper surface of the processing container, and a plurality of outer cells including the filter and the output terminal and arranged on the upper surface of the processing container to surround a vicinity of the inner cell.

(11) In the plasma processing apparatus of (10), the plurality of outer cells is arranged as 2n outer cells at equal intervals on a same circumference, the distributor distributes the electromagnetic wave to two of the outer cells and includes n systems each connected to a radio-frequency power source, and the frequency characteristics of the filters are different in respective outer cells belonging to a same system among the outer cells.

(12) In the plasma processing apparatus of (11), the frequency characteristics have two types within a same system, and different systems share the two types of frequencies.

(13) In the plasma processing apparatus of (10), the plurality of outer cells is arranged as n output cells at equal intervals on a same circumference, the distributor distributes the electromagnetic wave to n outer cells of the outer cells, and the frequency characteristics of the filters are different in respective outer cells adjacent to each other among the outer cells.

(14) In the plasma processing apparatus of (13), n is 3 or more, the frequency characteristics have three or more types, and the radio-frequency power source changes frequencies at a predetermined period.

(15) In the plasma processing apparatus of (14), n is 6, the frequency characteristics have three types, and the frequency characteristics of the filters are identical in the outer cell positioned in a point-symmetrical position about a center point of the upper surface of the processing container, among the plurality of outer cells.

(16) In the plasma processing apparatus of (14) or (15), the radio-frequency power source changes a time for maintaining each frequency in the changed frequencies.

(17) In the plasma processing apparatus of any one of (10) to (16), frequency characteristic of the matcher in the inner cell is different from frequency characteristics of the filters in the respective outer cells.

According to the present disclosure in some embodiments, it is possible to vary a power distribution ratio.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A distributor for distributing electromagnetic waves to a plurality of output terminals, the distributor comprising:
a power supply terminal configured to be electrically connected to a radio-frequency power source configured to be capable of varying frequency; and
a plurality of filters provided respectively at the plurality of output terminals to which the electromagnetic waves input to the power supply terminal are distributed,
wherein the plurality of filters is configured to have different frequency characteristics.

2. The distributor of claim 1, wherein each of the filters includes:
a housing including an input port and an output port each having an inner shaft and an outer cylinder, and configured to have a same potential as the outer cylinders of the input port and the output port;
a power supply fin connecting the inner shaft of the input port and the inner shaft of the output port, and provided within the housing; and
a ground fin connected to the housing at the same potential, and provided to protrude into the housing so as to be inserted between fins of the power supply fin.

3. The distributor of claim 2, wherein each of the number of the output terminals and the number of the filters is 2.

4. The distributor of claim 2, wherein each of the number of the output terminals and the number of the filters is 3 or more.

5. The distributor of claim 2, wherein a path between the power supply terminal and each of the filters is branched into branches in a middle, and
wherein a matcher configured to match the electromagnetic wave is provided between the power supply terminal and the branches.

6. The distributor of claim 2, wherein power of the electromagnetic wave output from each of the plurality of output terminals is distributed according to the frequency characteristics.

7. The distributor of claim 1, wherein each of the number of the output terminals and the number of the filters is 2.

8. The distributor of claim 1, wherein each of the number of the output terminals and the number of the filters is 3 or more.

9. The distributor of claim 1, wherein a path between the power supply terminal and each of the filters is branched into branches in a middle, and
wherein a matcher configured to match the electromagnetic wave is provided between the power supply terminal and the branches.

10. A plasma processing apparatus, comprising:
a processing container;
a radio-frequency power source configured to be capable of varying frequency;
a distributor configured to distribute electromagnetic wave output by the radio-frequency power source to a plurality of output terminals;
a slot antenna connected to each of the output terminal; and
a transmission window configured to transmit the electromagnetic wave radiated from the slot antenna, and configured to supply the electromagnetic wave into the processing container,
wherein the distributor includes:
a power supply terminal configured to be electrically connected to the radio-frequency power source; and
a plurality of filters provided respectively at the plurality of output terminals to which the electromagnetic wave input to the power supply terminal are distributed, and
wherein the plurality of filters is configured to have different frequency characteristics.

11. The plasma processing apparatus of claim 10, wherein a plurality of cells, each of which is a set of the filter, the output terminal, the slot antenna, and the transmission window, is arranged on a same circumference on an upper surface of the processing container.

12. The plasma processing apparatus of claim 11, wherein the plurality of cells is arranged as 2n cells at equal intervals on the circumference where n is an integer of 1 or more,
wherein the distributor distributes the electromagnetic wave to two of the cells and includes n systems each connected to the radio-frequency power source, and
wherein the frequency characteristics of the filters are different in the respective cells.

13. The plasma processing apparatus of claim 10, wherein a cell, which is a set of the slot antenna and the transmission window, includes:
an inner cell including a matcher for matching the electromagnetic wave, and arranged at a center of an upper surface of the processing container; and
a plurality of outer cells including the filter and the output terminal, and arranged on the upper surface of the processing container to surround a vicinity of the inner cell.

14. The plasma processing apparatus of claim 13, wherein the plurality of outer cells is arranged as 2n outer cells at equal intervals on a same circumference where n is an integer of 1 or more,
wherein the distributor distributes the electromagnetic wave to two of the outer cells and includes n systems each connected to the radio-frequency power source, and
wherein the frequency characteristics of the filters are different in respective outer cells belonging to a same system among the outer cells.

15. The plasma processing apparatus of claim 14, wherein the frequency characteristics have two types within a same system, and
wherein different systems share two types of frequencies.

16. The plasma processing apparatus of claim 13, wherein the plurality of outer cells is arranged as n output cells at equal intervals on a same circumference where n is an integer of 2 or more,
wherein the distributor distributes the electromagnetic wave to n outer cells of the outer cells, and
wherein the frequency characteristics of the filters are different in respective outer cells adjacent to each other among the outer cells.

17. The plasma processing apparatus of claim 16, wherein n is 3 or more,
wherein the frequency characteristics have three or more types, and
wherein the radio-frequency power source changes frequencies at a predetermined period.

18. The plasma processing apparatus of claim 17, wherein n is 6,
wherein the frequency characteristics have three types, and
wherein the frequency characteristics of the filters are identical in the outer cells positioned in a point-symmetrical position about a center point of the upper surface of the processing container, among the plurality of outer cells.

19. The plasma processing apparatus of claim 18, wherein with respect to the changed frequencies, the radio-frequency power source changes a time for maintaining each frequency.

20. The plasma processing apparatus of claim 13, wherein frequency characteristic of the matcher in the inner cell is different from the frequency characteristics of the filters in the respective outer cells.
